(19) United States
(12) Patent Application Publication
(10) Pub. No.: US 2025/0286491 A1
(43) Pub. Date: Sep. 11, 2025

(54) MOTOR CONTROLLER MODULE AND METHOD OF USE

(71) Applicant: James Leych Lau, Tustin, CA (US)

(72) Inventor: James Leych Lau, Tustin, CA (US)

(21) Appl. No.: 19/072,472

(22) Filed: Mar. 6, 2025

Related U.S. Application Data
(60) Provisional application No. 63/561,863, filed on Mar. 6, 2024.

(51) Int. Cl. H02P 23/00; H03K 17/56; H03K 17/78; H03K 19/0175

(52) U.S. Cl. CPC H02P 23/0077; H03K 17/56; H03K 17/78; H03K 19/017572

(57) ABSTRACT

A method of operating a motor using a motor controller module, wherein the motor controller module is configured for electrical communication with a power source and the motor, the method having the steps of: obtaining an input signal from the power source, generating an output signal by manipulating the input signal to skip at least a portion of a signal cycle of the input signal, and transmitting the output signal to the motor. The motor controller module may be configured to manipulate the input signal to generate the output signal by selectively actuating a plurality of switches to skip the at least a portion of the input signal. By selectively skipping whole or partial signal cycles in the output signal while sufficient motor operating conditions are achieved, the amount of power sent to the motor may be reduced, thus saving energy and reducing motor heating and wear.

### CROSS-REFERENCE TO RELATED APPLICATIONS

This application claims the benefit of U.S. Provisional Application No. 63/561,863, filed on Mar. 6, 2024, which is hereby incorporated by reference, to the extent that that it is not conflicting with the present application.

### BACKGROUND OF INVENTION

### 1. Field of the Invention

The invention relates generally to motor controller modules and specifically to motor controller modules configured to reduce energy consumption.

### 2. Description of the Related Art

In the industry, most motor speed controllers are now constructed using a suitable Variable Frequency Drive (VFD). For example, over 85% of all motor speed controllers are based on VFD technologies. The VFD can adjust the speed of the motor as needed to run at a lower speed at partial load, reducing energy consumption. The VFD can also reduce the motor starting current and gradually increase the speed to further reduce energy consumption. In said embodiments, the resultant motor speed (rpms) is defined as (120*Frequency of input signal)/number of poles. As such, the frequency of an input signal sent to the motor can be varied, and thus the motor speed can be controlled, accordingly. For a motor speed controller having a VFD, the cost of operation is generally high, and the VFD uses digital pulses to emulate the sinusoidal waveforms, thus creating undesired heating of the motor coils, which can negatively influence motor performance and longevity. The digital pulses or pulse width modulations (“PWMs”) are rapid changes in voltages with very sharp edges. The VFD controlled motor can therefore stress the windings and insulation, potentially reducing the lifespan of the motor. VFDs can also introduce harmonics into the electrical system which can lead to overheating, increased losses and premature failure of equipment. Therefore, VFDs lack a suitable mechanism for reducing energy consumption while maintaining suitable motor performance.

Therefore, there is a need to provide a motor controller module configured to manipulate the signal sent to a motor to control the motor speed and starting motor current to gradually increase motor speed at start up, and to facilitate further reduced energy consumption while maintaining motor performance by minimizing or eliminating the negative effects of a traditional PWM based VFDs

The aspects or the problems and the associated solutions presented in this section could be or could have been pursued; they are not necessarily approaches that have been previously conceived or pursued. It should be understood that structural and/or logical modifications could be made by someone of ordinary skills in the art without departing from the scope of the invention. Therefore, unless otherwise indicated, it should not be assumed that any of the approaches presented in this section qualify as prior art merely by virtue of their presence in this section of the application.

### BRIEF INVENTION SUMMARY

This Summary is provided to introduce a selection of concepts in a simplified form that are further described below in the Detailed Description. This Summary is not intended to identify key aspects or essential aspects of the claimed subject matter. Moreover, this Summary is not intended for use as an aid in determining the scope of the claimed subject matter.

In an aspect, a motor controller module configured for electrical communication with a motor and a power source is provided, the motor controller module comprising: a controller unit; an optocoupler configured for electrical communication with the controller unit and the power source; an optotriac configured for electrical communication with the controller unit; and a plurality of switches, wherein each switch of the plurality of switches is configured for electrical communication with the optotriac and the motor; wherein the motor controller module is configured to receive an input signal from the power source, wherein the controller unit is configured to manipulate the received input signal by actuating at least one switch of the plurality of switches to generate an output signal, wherein the output signal skips at least one portion of a signal cycle of the input signal, and transmit the output signal to the motor. Thus, an advantage is that energy consumption may be reduced while maintaining the necessary motor performance by skipping whole or partial cycles of the signal output to the motor at specific intervals. In this way, the inertia of the motor and the momentum of the residual magnetic flux may be utilized to allow the motor to continue rotating while not being actively powered (e.g., during a skipped cycle), thus facilitating continued motor operation while using less power overall. Another advantage is that due to only delivering the necessary amount of power to the motor to facilitate continued operation, excess heating of the motor may be avoided, thus maintaining motor efficiency and preventing unnecessary wear on the motor. This advantage may be particularly relevant for devices having motors that operate continuously or for long durations of time, as prolonged heating of motor elements may lead to damage and subsequent failure.

In another aspect, a motor controller module is provided, the motor controller module comprising: a controller unit configured for electrical communication with a motor and a power source; a plurality of switches, wherein each switch of the plurality of switches is configured for electrical communication with the controller unit and the motor; wherein the motor controller module is configured to receive an input signal from the power source, generate an output signal by manipulating the input signal to skip at least a portion of at least one signal cycle and transmit the output signal to the motor, wherein the controller unit is configured to receive the input signal and manipulate the input signal by selectively actuating at least one switch of the plurality of switches. Again, an advantage is that energy consumption may be reduced while maintaining the necessary motor performance by skipping whole or partial cycles of the signal output to the motor at specific intervals. In this way, the inertia of the motor and the momentum of the residual magnetic flux may be utilized to allow the motor to continue rotating while not being actively powered (e.g., during a skipped cycle), thus facilitating continued motor operation while using less power overall. Another advantage is that due to only delivering the necessary amount of power to the motor to facilitate continued operation, excess heating of the motor may be avoided, thus maintaining motor efficiency and preventing unnecessary wear on the motor. This advantage may be particularly relevant for devices having motors that operate continuously or for long durations of time, as prolonged heating of motor elements may lead to damage and subsequent failure.

In another aspect, a method of operating a motor using a motor controller module, wherein the motor controller module is configured for electrical communication with the motor and a power source, the motor controller module having: a controller unit configured for electrical communication with the power source and a plurality of switches, wherein each switch of the plurality of switches is configured for electrical communication with the controller unit is provided, the method comprising the steps of: obtaining an input signal from the power source; generating an output signal by manipulating the input signal to skip at least a portion of the input signal through selective actuation of at least one switch of the plurality of switches; and transmitting the output signal to the motor. Again, an advantage is that energy consumption may be reduced while maintaining the necessary motor performance by skipping whole or partial cycles of the signal output to the motor at specific intervals. In this way, the inertia of the motor and the momentum of the residual magnetic flux may be utilized to allow the motor to continue rotating while not being actively powered (e.g., during a skipped cycle), thus facilitating continued motor operation while using less power overall. Another advantage is that due to only delivering the necessary amount of power to the motor to facilitate continued operation, excess heating of the motor may be avoided, thus maintaining motor efficiency and preventing unnecessary wear on the motor. This advantage may be particularly relevant for devices having motors that operate continuously or for long durations of time, as prolonged heating of motor elements may lead to damage and subsequent failure.

The above aspects or examples and advantages, as well as other aspects or examples and advantages, will become apparent from the ensuing description and accompanying drawings.

### BRIEF DESCRIPTION OF THE DRAWINGS

For exemplification purposes, and not for limitation purposes, aspects, embodiments or examples of the invention are illustrated in the figures of the accompanying drawings, in which:

FIG. 1 illustrates a block diagram of a motor controller drive, according to an aspect.

FIG. 2 illustrates a schematic diagram of a motor controller drive, according to an aspect.

FIG. 3 illustrates a schematic diagram of an alternative embodiment of a motor controller drive, according to an aspect.

FIG. 4A illustrates a voltage input to the motor controller module, according to an aspect.

FIG. 4B illustrates a conditioned voltage output to the motor coil, wherein every other cycle is skipped, according to an aspect.

FIG. 4C illustrates a voltage input signal from a power source and a conditioned voltage output signal sent to a motor coil, according to an aspect.

FIG. 4D illustrates the voltage input signal sent to a motor controller overlayed on the conditioned voltage output signal sent to the corresponding motor windings, according to an aspect.

FIG. 4E illustrates a conditioned voltage output and a corresponding conditioned current output sent to a motor, with 1.5 cycles passing through to the motor windings over a certain number of cycles, according to an aspect.

FIG. 4F illustrates a conditioned output voltage sent into the motor winding, wherein the passed through waveforms reduce their average amplitude from cycle 1 to cycle 2 to cycle 3, until the cycle stops passing through or is skipped, according to an aspect.

FIG. 5A illustrates a voltage input to the motor controller drive, according to an aspect.

FIG. 5B illustrates a conditioned voltage output to a motor coil, wherein multiple cycles are skipped, according to an aspect.

FIG. 5C illustrates a conditioned voltage output to a motor coil, wherein approximately 3.5 cycles are passed through, and 4 cycles are skipped, according to an aspect.

FIG. 5D illustrates an expanded timeline of FIG. 5C to show the number of cycles passing through to the motor winding are periodic and can be controlled or adjusted, according to an aspect.

FIG. 6 illustrates a schematic diagram of a modified variable frequency drive (VFD) having a controller unit, according to an aspect.

FIG. 7A illustrates a voltage output to a motor coil for a typical variable frequency drive, according to an aspect.

FIG. 7B illustrates a voltage output to a motor coil for a modified variable frequency drive, wherein one cycle is skipped, according to an aspect.

FIG. 7C illustrates a voltage output to a motor coil for a modified variable frequency drive, wherein partial cycles are skipped, according to an aspect.

### DETAILED DESCRIPTION

What follows is a description of various aspects, embodiments and/or examples in which the invention may be practiced. Reference will be made to the attached drawings, and the information included in the drawings is part of this detailed description. The aspects, embodiments and/or examples described herein are presented for exemplification purposes, and not for limitation purposes.

For the following description, it can be assumed that most correspondingly labeled elements across the figures (e.g., 101 and 201, etc.) possess the same characteristics and are subject to the same structure and function. If there is a difference between correspondingly labeled elements that is not pointed out, and this difference results in a non-corresponding structure or function of an element for a particular embodiment, example or aspect, then the conflicting description given for that particular embodiment, example or aspect shall govern.

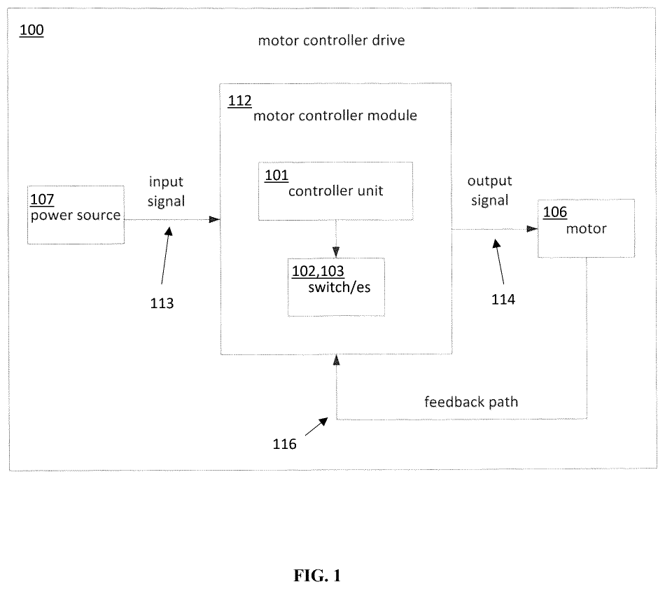

FIG. 1 illustrates a block diagram of a motor controller drive 100, according to an aspect. In an embodiment, the motor controller drive 100 may comprise a motor controller module 112 coupled to and in electrical communication with a power source 107 and a motor 106. In some aspects, the motor controller module 112 may be configured to obtain input signal 113 from the power source 107, generate an output signal 114 and transmit the output signal 114 to the motor 106. The motor 106 then may operate according to the output signal 114. In some aspects, the motor controller module 112 may be configured to generate the output signal 114 by manipulating the input signal 113 to skip at least a portion of the input signal 113 (in the corresponding output signal 114 sent to the motor), such as at least a portion of at least a signal cycle of the input signal.

In some aspects, the motor controller module 112 may comprise a controller unit 101 and a plurality of switches 102, 103 coupled with/in electrical communication with the controller unit 101. In some aspects, the controller unit 101 may be implemented by (e.g., be in the form of) one or more of an analog processing unit (APU), an optical processing unit (OPU), a graphics processing unit (GPU), and a microcontroller unit (MCU), or any other controlling unit that may be configured to manipulate the input signal 113 to generate an output signal 114 with the desired waveform. The controller unit 101 may be configured to actuate one or more of the plurality of switches 102, 103 to control which signal cycle(s) of the input cycle are to be skipped in the output signal, thus manipulating the input signal to skip at least a portion of at least one signal cycle.

In some aspects, the motor controller module 112 may be further in electrical communication with the motor 106 via a feedback path 116. In some aspects, the controller unit 101 may be further configured to obtain an indication of operation of the motor 106 (e.g., relevant motor operation information/motor operation feedback information) from the motor 106 via the feedback path 116. In some aspects, the controller unit 101 may be further configured to adjust or maintain the actuation of the one or more switches of the plurality of switches 102, 103 in response to the indication of operation of the motor provided over the feedback path 116.

Thus, an advantage of the disclosed motor controller drive 100 is that energy consumption may be reduced while maintaining the necessary motor performance by skipping whole or partial cycles (from the input signal) in the signal output to the motor at specific intervals. In this way, the inertia of the motor may be utilized to allow it to continue rotating while not being actively powered (e.g., during a skipped cycle), thus facilitating continued motor operation while using less power overall and at reduced motor speed. Another advantage is that due to only delivering the necessary amount of power to the motor to facilitate continued operation, excess heating of the motor may be avoided, thus maintaining motor efficiency and preventing unnecessary wear on the motor. This advantage may be particularly relevant for devices having motors that operate continuously or for long durations of time, as prolonged heating of motor elements may lead to motor winding damage and subsequent failure.

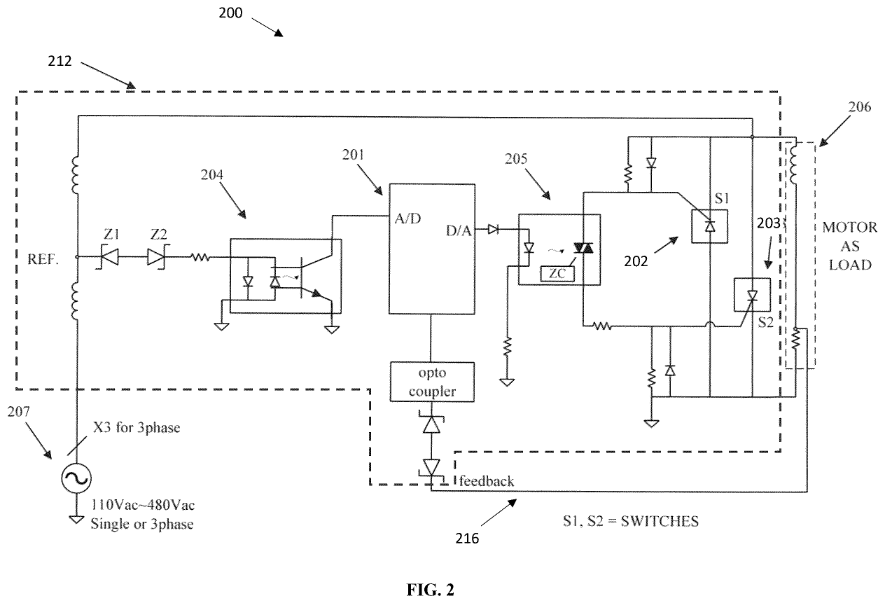

Specific implementation details of the motor controller drive 100 are described below in connection with further figures, for example, FIGS. 2, 3 and 6. In an alternative embodiment, the motor controller drive can also be modified to power an electric heater or any other application requiring fast feedback and a feedforward response loop.

FIG. 2 illustrates a schematic diagram of a motor controller drive 200, according to an aspect. The motor controller drive 200 of FIG. 2, in particular the controller unit 201, may be configured to control the speed of an associated motor 206 through manipulation of an input voltage signal (e.g., the input signal 113 of FIG. 1) provided from an associated power source 207. As will be described in greater detail hereinbelow, the motor controller drive 200 may be configured to run a motor 206 more efficiently by using less energy to achieve the necessary motor function and different motor speed, when compared to a conventional VFD. In this embodiment, the motor controller drive 200 may be utilized as an energy-saving alternative to a conventional VFD to control motor operation. The new method utilized by the disclosed motor controller drive 200 may control the number of sinusoidal signal cycles received from an input signal that are sent into the motor windings (as the output signal) over a set amount of time.

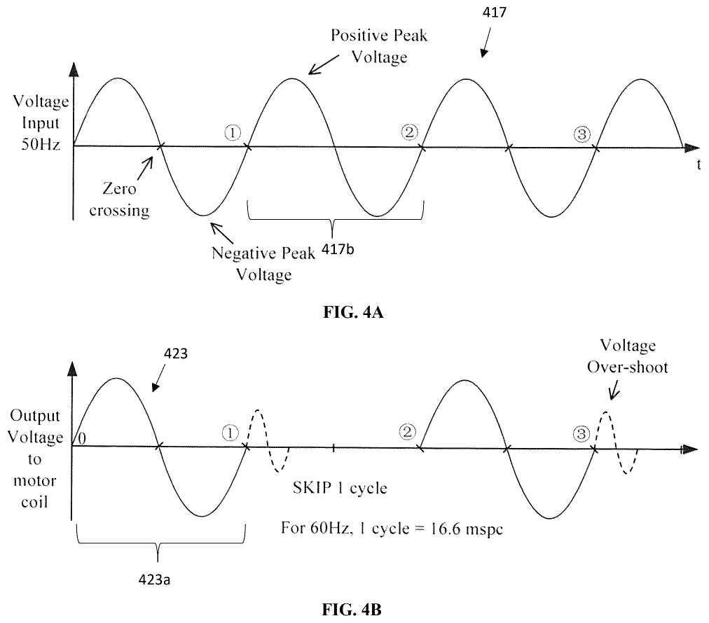

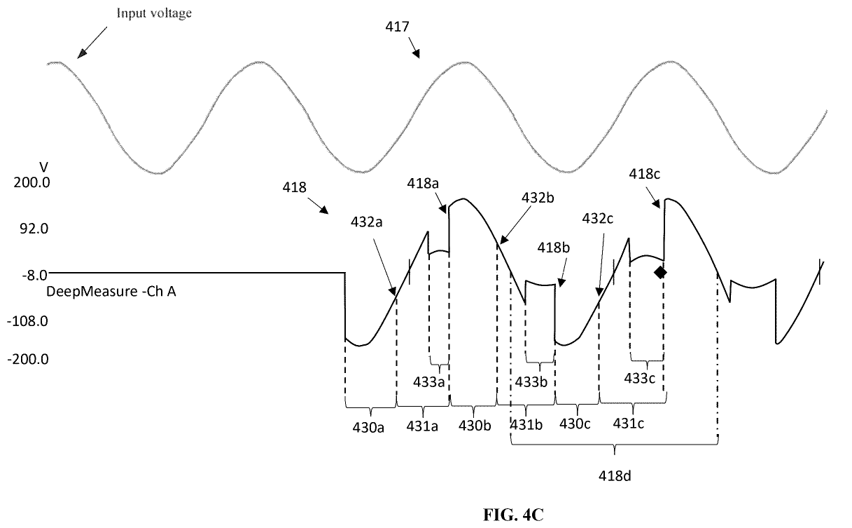

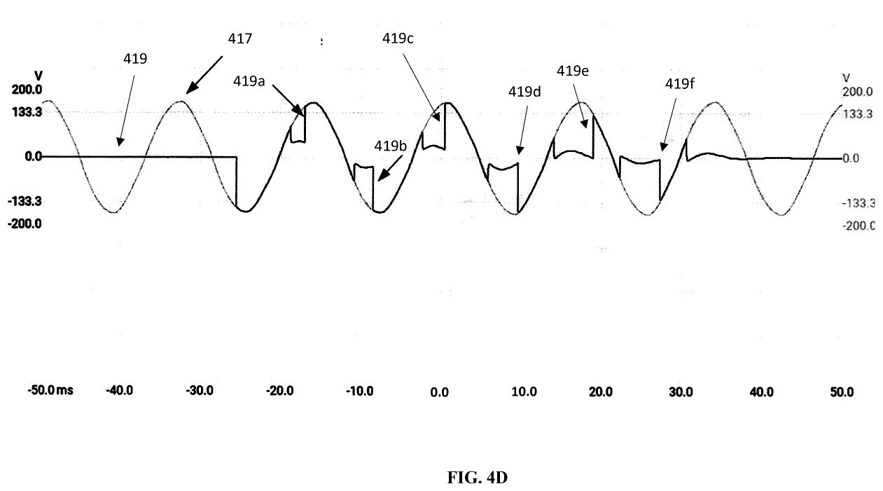

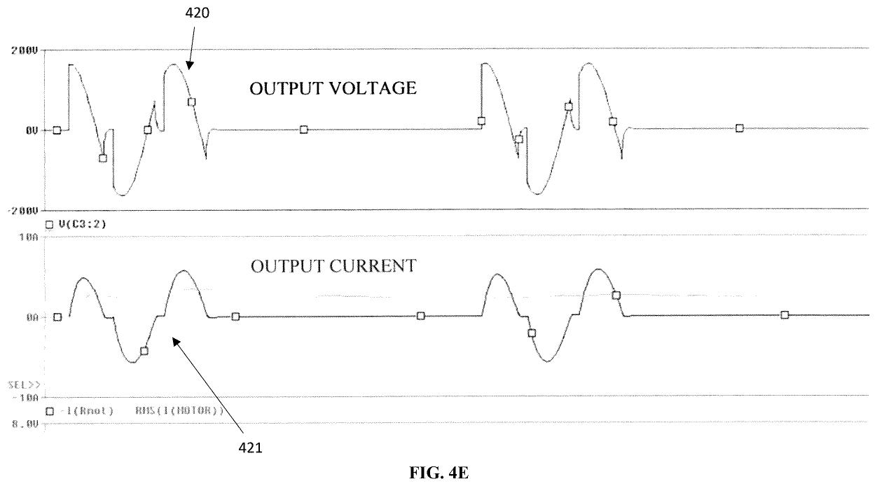

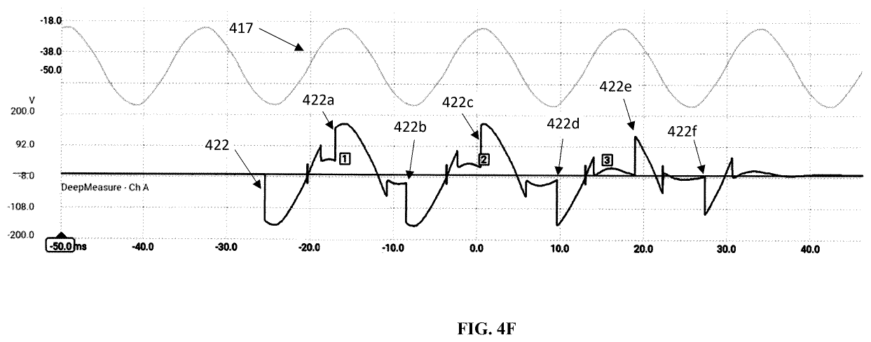

For example, as seen in FIG. 4B, the motor control drive 200 may be configured to allow a single full 60 Hz signal cycle to be sent to the motor, and then may stop sending a signal to the motor for the next cycle, and then repeat with another 60 Hz signal cycle, and another cycle pause, etc. In other words, first a full 60 Hz signal cycle of voltage (or current) may be sent to the motor 206, followed by a full cycle/period of 0 volts (or 0 current) being sent to the motor 206, which then repeats. In this embodiment, the associated motor may receive, on average, 30 Hz of signal over two consecutive cycles (which is the average of the two consecutive cycles/periods, one with 60 Hz, the other with 0 Hz) by skipping a full waveform every other signal cycle (e.g., skipping every other signal cycle), and thus may reduce its speed by 50%, when compared to receiving repeated consecutive 60 Hz cycles. As is understood, the output signals/waveforms (such as those seen in FIG. 4B, 5B) being sent to the motor could be showing voltage or current depending on their implementation. In an embodiment, for motor coils, the current waveform is the driving force, based on torque being defined as proportional to N*I (wherein N is the number of windings, and I is the current in amperes).

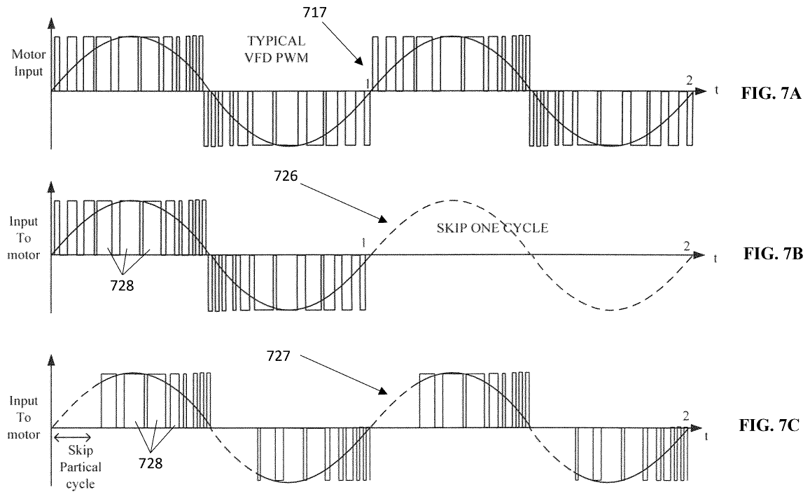

In an embodiment, the disclosed motor controller drive 200 may be configured to control the speed of a motor 206 by skipping full signal cycles, as shown in FIG. 4B, while allowing the inertia of the running motor 206 to facilitate continued motor rotation while the motor is not being actively powered. In an alternative embodiment, the disclosed motor controller drive 200 may be configured to skip partial signal cycles, similarly to what is shown in FIG. 7C. In said embodiment, the disclosed motor controller drive 200 may skip partial signal cycles based on feedback control of loads, wherein feedback may be provided to the motor control module 212 over the feedback path 216), while maintaining the speed of the motor 206, as a result of not changing the frequency of the output signal received by the motor 206. In said alternative embodiment, by only skipping partial cycles, the motor controller drive 200 is not changing the speed/RPMs of the motor 206, but is still saving energy by delivering partial cycles to the motor at 0V/0 Amps (e.g., delivering less overall energy to the motor.) In other words, the motor controller drive 200 may be configured to skip partial cycles when the load is reduced temporarily, due to the nature of loading. For instance, for a motor running a conveyor belt, if a lighter load is placed on the conveyor belt temporarily, the load on the motor will be reduced, and the feedback system of the motor controller drive 200 may instruct the controller unit 201 to skip some partial cycles, etc.

In an embodiment, the disclosed motor controller drive 200 may be configured to control the torque and speed of a motor 206 by turning on the power to the motor winding at a defined angle to allow for the “over shoot” and “under shoot” of the magnetic flux to help the motor rotor to keep spinning, as shown in FIG. 4C, thus allowing the residual magnetic flux of the magnetic field of motor 206 stator to facilitate continued motor rotation while the motor is not being actively powered (e.g., while power is not being actively sent to the motor 206 from the motor controller module 212). In other words, the power is removed (e.g., no power is being provided to the motor) just before the rotor reaches the change in the polarity as the voltage and current swings from positive to negative and vice versa, and the opposite polarity power is only turned on (manifested as steps 418a and 418b in FIG. 4C) after the residual flux has collapsed completely. Therefore, energy is saved by not powering the motor windings during this transitional period and the residual magnetic flux (and the residual momentum) may be exploited to facilitate continued rotation of the motor 206. This phenomena of turning on the power to the motor winding at a defined angle to allow for the over shoot and under shoot of the magnetic flux will be described in greater detail hereinbelow.

As seen in FIG. 2, the disclosed motor controller drive 200 may comprise a controller unit 201 configured to perform an A/D (analog to digital) conversion to sample the input waveform/signal from a power source 207, proceed with DSP (digital signal processing), and then perform a D/A (digital to analog) conversion back to an analog signal, and use the resultant analog signal leaving the controller unit 201 to control corresponding switches 202, 203 that allow portions of the input signal into the motor windings. In this way, the input signal may be converted into the output signal through selective actuation of the switches 202, 203 by the controller unit 201 before being sent to the motor 206. In an embodiment, the motor controller drive 200 may further comprise a first switch 202 and a second switch 203, both of which may be in electrical communication with the controller unit 201. In said embodiment, the controller unit 201 may be configured to manipulate the first and second switches 202, 203 in order to control the amount and pattern of sinusoidal signals cycles from the input signal that are sent to the motor 206, in the form of the output signal. This will result in the motor 206 being powered intermittently (e.g., non-continuously), allowing the inertia of the motor 206 to facilitate continued motor rotation while the motor 206 is not actively being powered, thus increasing efficiency, as described herein.

As seen in FIG. 2, the motor controller drive 200 may have optocouplers and similar devices in order to establish communication between elements. In an embodiment, an optocoupler 204 may be in communication with the power source 207 and the controller unit 201, and an optotriac 205 may be in communication with the controller unit 201 and the first and second switches 202, 203. Furthermore, in an embodiment, the switches 202, 203 may be in electrical communication with the power source 207, such that the input signal may be manipulated by the selective actuation of the switches 202, 203 in order to generate the output signal sent to the motor 206. As is understood, the interconnections/communication depicted within the motor controller drive 200 of FIG. 2 may be configured to facilitate the delivery of intermittent 60 hz signal cycles to the motor 206, thus resulting in intermittent powering of the motor 206, as will be described in greater detail hereinbelow. For simplicity, as described in FIG. 1, the motor controller drive 200 may be described as comprising a power source 207, a motor controller module 212 in electrical communication with the power source 207, and a motor 206 in electrical communication with the motor controller module 212

As is understood with optocouplers, optotriacs, and similar electrical elements that utilize optical transmission as an intermediary step, the optocoupler 204/optotriac 205 may utilize optical communication between internal structures to facilitate electrical communication between associated external elements. For example, while the optocoupler 204 may transfer electrical signals between separate elements using light, it may be said that the optocoupler 204 is configured to facilitate “electrical communication” between the power source 207 and the controller unit 201 (e.g., the controller unit 201 is in electrical communication with the power source 207 and the optocoupler 204 is in electrical communication with the controller unit 201 and power source 207). Similarly, the optotriac 205 may be configured to facilitate “electrical communication” between the controller unit 201 and the switches 202, 203 (e.g., the controller unit 201 is in electrical communication with the first switch 202 and the second switch 203, and the optotriac 205 is in electrical communication with the controller unit 201 and the switches 202, 203.) In an embodiment, the disclosed optocoupler 205 and optotriac 206 may be described as components of the motor controller module 212, such that the motor controller module comprises an optocoupler 204, a controller unit 201 in electrical communication with the optocoupler, an optotriac 205 in electrical communication with the controller unit 201 and a pair of switches 202, 203 in electrical communication with the optotriac 205, as seen in FIG. 2.

In order to ensure that motor operation is suitably maintained, the controller unit 201 may be configured to receive feedback (over the feedback path 216) based on motor operation. In an embodiment, the controller unit 201 may be configured to automatically provide power to the motor 206 (even during a skipped signal cycle in the output signal) if the motor 206 is not operating at the required specifications (e.g., RPM, torque, etc.) at a given time. As such, suitable amounts of power may be provided to the motor 206 as needed, wherein signal cycles will be skipped in the output signal, when possible to do so (e.g., when suitable motor operations can be maintained), to reduce energy consumption.

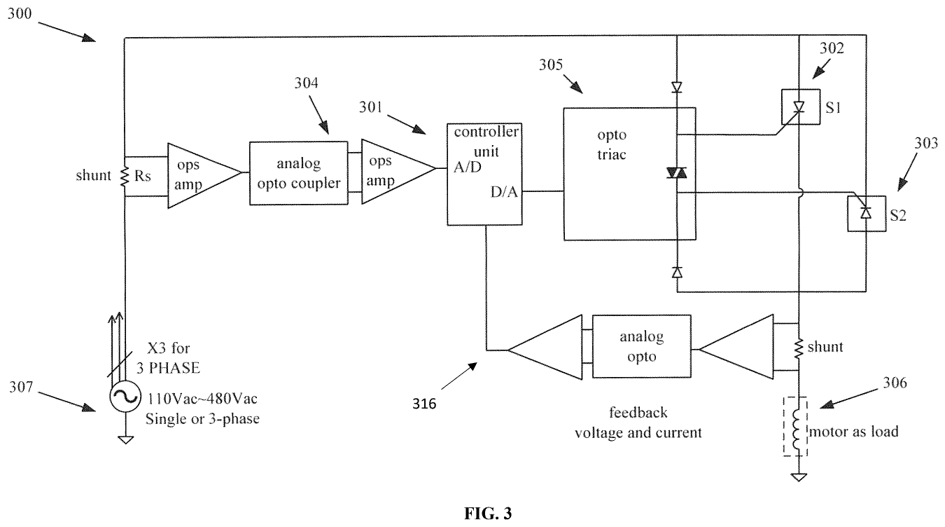

FIG. 3 illustrates a schematic diagram of an alternative embodiment of a motor controller drive 300, according to an aspect. Much like the motor controller drive 200 of FIG. 2, the alternative embodiment of the motor controller drive 300 of FIG. 3 may also utilize a controller unit 301 configured to perform A/D conversion to an incoming input waveform/signal from a power source 307, followed by digital signal processing, and then a D/A conversion. As disclosed hereinabove, the generated analog signal from the controller unit 301 may be configured to control corresponding switches, such as a first switch 302 and a second switch 303, to allow an output signal generated from the input signal having whole and/or partial skipped signal cycles to be sent into the motor windings. It should be understood that while structures of the motor controller drive 200 of FIG. 2 and the motor control drive 300 of FIG. 3 may differ somewhat regarding their structure and arrangement of elements, both motor controller drives 200, 300 are configured to provide the described signal cycle skipping capabilities to intermittently power a motor, thus facilitating reduced energy usage and increased efficiency, while optimizing motor performance.

In an embodiment, the motor controller drive 300 may be configured to monitor motor operation to ensure suitable motor operation is maintained and provide feedback to the controller unit 301 over a feedback path 316, accordingly. For example, if the feedback collected by the controller unit 301 indicates that the current inertia of the motor has fallen too low, the controller unit 301 may force the motor 306 to restart operation early by sending another powered 60 hz signal to the motor 306 before the skipped cycle of the output signal has ended. This in turn may help to optimize energy usage while still making sure the motor is operating as needed.

As with the motor controller drive 200 of FIG. 2, the motor controller drive 300 of FIG. 3 may also comprise an optocoupler 304 and an optotriac 305. In an embodiment, the optocoupler 304 may be in electrical communication with a power source 307 and the controller unit 301, thus facilitating electrical communication between the power source 307 and the controller unit 301. In said embodiment, the optotriac 305 may be in electrical communication with the controller unit 301 and the first and second switches 302, 303, thus facilitating electrical communication between the controller unit 301 and the first and second switches 302, 303.

In an embodiment, a motor controller drive 300 may comprise a power source 307, a controller unit 301 in electrical communication with the power source 307, a first switch 302 in electrical communication with the controller unit 301, a second switch 303 in electrical communication with the controller unit 301 and a motor in electrical communication with the first and second switches 302, 303. In this embodiment, the controller unit 301 may be configured to manipulate a voltage input signal from the power source 307, through operation of the first and second switches 302, 303, to generate a conditioned voltage output signal (“voltage output signal”, “voltage output”, “conditioned voltage output”), wherein the conditioned voltage output signal skips at least one signal cycle (partial or whole) of the original voltage input signal (“voltage input”) and is received by the motor 306. It should be understood that when describing skipping signal cycles, either full signal cycle(s) may be skipped, similar to what is shown in FIG. 4B, or a partial signal cycle may be skipped, similar to what is shown in FIG. 7C. The controller units 201, 301 as illustrated in FIG. 2-3 may be implemented by any one or more of an analog processing unit (APU), an optical processing unit (OPU), a graphics processing unit (GPU), and a microcontroller unit (MCU), or any other controller unit that may be configured to manipulate the input signal to generate an output signal with desired waveform. It is recognized by those skilled in the art that any equivalents or variants to the controller unit 201, 301 would not extend beyond the scope and spirit of the original disclosure.

FIG. 4A illustrates a voltage input 417 to the motor controller module, according to an aspect. FIG. 4B illustrates a conditioned voltage output 423 to the motor coil, wherein every other cycle is skipped, according to an aspect. As is understood, while the disclosed motor controller module, such as motor controller module 212 of FIG. 2, is configured to control a signal sent to the motor, such as a voltage output signal 423, the motor controller module may not be configured to change the input waveform frequency across the board, as in the case of the VFD implementation. Instead, the disclosed motor controller module may be configured to change the number of original single 60 Hz waveforms or multiple single 60 Hz waveforms in the voltage output signal 423 that enters the motor windings, as is shown when comparing the voltage input 417 and voltage output 423 graphs of FIGS. 4A and 4B, respectively. As described hereinabove, the quantity of signal cycles sent to the motor (which may also be described as being signal cycles that are “passed through”), and the quantity of signal cycles skipped (not sent to the motor), may be varied in accordance with the needs of the associated system utilizing the motor (e.g., required RPMs, torque, efficiency, etc.) The disclosed controller unit, such as controller unit 201, 301, of FIG. 2-3, may be configured to control the corresponding switches of the motor controller module, such as first switch 202, 302 and second switch 203, 303 of FIG. 2-3 The controlling of the switches may be done in order to control how many signal cycles of the original voltage input signal 417 are provided in the voltage output signal 423, and thus how many signal cycles are sent to the motor, and how many signal cycles are skipped. By skipping certain signal cycles of the original voltage input signal 417, the voltage output signal 423 may thusly be configured to facilitate intermittent motor operation.

FIG. 4C illustrates a voltage input signal 417 from a power source and a conditioned voltage output signal 418 sent to a motor coil, according to an aspect. As, is understood, the voltage output signal 418 of FIG. 4C illustrates conditioning that may be done to those cycles that are not completely skipped, wherein the passing through/sent cycles are powered or turned on at a defined cycle angle, manifested as the first “positive going portion” of the cycle having a first vertical step 418a and the first “negative going portion” of the cycle having a second vertical step 418b. These cycles can also be partially powered off and powered on again to save some energy within each cycle itself (e.g., portions of the whole signal cycles may be powered off/signal cycles are “partially powered off”). The vertical steps 418a, 418b (sudden increase in voltage magnitude) on the time scale of the motor controller module output (the conditioned voltage output signal 418 of FIG. 4C) illustrate where the power is turned back on after it has been turned off, wherein the power was turned off before the voltage output signal 418 crossed over the zero crossing (e.g., 0V on the Y-axis). This conditioning of the voltage output signal 418 occurs on both the positive half and negative half of signal cycles. By turning off the power to the motor winding before it crosses the zero crossing, the momentum of the magnetic flux is not being halted, impeded or “braked”, but instead be utilized to continue powering the motor, thus providing some energy savings. Then after the residual magnetic flux in the motor coil has died down and can longer sustain the required motion of the motor, the motor winding is powered on again to maintain motor operation.

As articulated hereinabove, the conditioned voltage output signal 418 may be characterized by portions wherein the conditioned voltage output signal 418 is powered on, such as first powered on portion 430a, second powered on portion 430b and third powered on portion 430c, and portions wherein the conditioned output signal 418 are powered off, such as first powered off portion 431a, second powered off portion 431b and third powered off portion 431c. In an embodiment, power off points 432a, 432b, 432c may be disposed between the powered on portions 430a, 430b, 430c and the corresponding powered off portions 431a, 431b, 431c. Similarly, a power on point 418a, 418b, 418c may be disposed between each powered off portion and the subsequent powered on portion. For example, the conditioned voltage output signal 418 may have a first powered on portion 430a which ends at a first power off point 432a and is followed by a first powered off portion 431a. This first powered off portion 431a then ends at a first power on point 418a and is then followed by a second powered on portion 430b. This pattern of a powered on portion ended by a power off point, followed by a powered off portion ended by a power on point may continue as long as is necessary in order to provide the necessary power to the motor to provide sufficient performance. As is understood, the power off points 432a-432c present in the output signal 418 may occur/be positioned at a non-zero voltages (before the crossing over the zero crossing) of the corresponding signal cycle, as seen in FIG. 4C.

During each powered off portion 431a-431c, the residual magnetic flux in the motor coil is utilized to continue motor operation after the power is turned off. However, as time goes on, this residual magnetic flux starts to collapse, as indicated by first collapse portion 433a, second collapse portion 433b and third collapse portion 433c. As can be seen in FIG. 4C, the voltage of the conditioned voltage output signal during these collapse portions is reduced in magnitude (when compared to the corresponding portion of the voltage input signal 417), and thus is closer to 0V, thus reducing RMS voltage of the conditioned voltage output signal 418 during these collapse portions 433a-433c. As described hereinabove, as the collapse portions 433a-433c completely collapse, the conditioned voltage output signal cycle will be turned back on, as indicated by the corresponding power on points 418a-418c, to ensure continued motor operation.

It should be understood that the specific positioning/defined cycle angle of the power off points 432a-432c and the power on points 418a-418c, and thus the durations of the powered on portion 430a-430c, the powered off portion 431a-431c and the collapse portions 433a-433c in FIG. 4C are merely provided as an example. For example, in FIG. 4C, the duration of each subsequent collapse portion may increase. This trend may not be present in each embodiment of the conditioned voltage output signal. In an embodiment, the positioning/defined cycle angle/timing of each of these described points and portions of FIG. 4C may be controlled by the controller unit, such as controller unit 201 of FIG. 2, in order to provide sufficient power to a motor, while providing energy savings by only providing power to the motor intermittently as necessary.

As is understood, power on points 418a-418c and power off points 432a-432c of output signal 418 may not occur at the start/end of a corresponding cycle. As seen in FIG. 4C, cycle 418d of output signal 418 is defined independently of the power on/off points and power on/off durations, as the power on/off points and power on/off durations of the output signal may be determined dynamically by the controller unit, based upon the need of the motor receiving the output signal.

FIG. 4D illustrates the voltage input signal 417 sent to a motor controller overlayed on the conditioned voltage output signal 419 sent to the corresponding motor windings, according to an aspect. As can be seen in the embodiment of FIG. 4D, the time taken to power off and power on the motor again (as articulated in the powered on portions 430a-430c and the powered off portions 431a-431c of FIG. 4C) can vary, and this variance can allow for the control of the amplitude of the current and thus the average current sent into the motor winding, in order to save energy. By varying the time duration during which the power is turned off within each cycle (during which no power from the power source is provided to the motor, but residual magnetic flux may be utilized to continue motor operation), the precise amount of current can be delivered to the motor to match the current needed for the motor load conditions. These variable time duration powered off and powered on portions present per cycle can be determined by the controller unit. In an embodiment, the timing of the power on points 419a-419f after the power off points (e.g. the duration of the powered off portion) can be timed to coincide exactly with the complete collapse of the magnetic flux, such that power is returned to the motor before the complete collapse of the magnetic flux, thereby providing full power to the motor rotor, while saving energy in the microsecond duration when the power was off. Once this microsecond duration of energy saving is computed over many hours, the energy savings can be substantial. In other words, the exact durations of the powered off portions and the powered on portions may be dictated by the amount of time the residual magnetic flux can continue to provide sufficient motor operation.

While the sequence of power on points 419a-419f of output signal 419 may be showing progressive sequence, wherein the power off durations increase with each consecutive cycle, it should be understood that other sequences of powered off portions are also considered. For example, in an embodiment, the sequence of powered off portions of output signal 419 may be reversed in order, such that a first signal cycle has longest powered off portion, the second signal cycle has the second longest powered off portion, the third signal cycle has the third longest powered off portion, and so on and so forth, such that the duration of each powered off portion decreases with each consecutive signal cycle. In further alternative embodiments, the sequence and duration of each powered off portion may be random or dictated by the instantaneous needs of the motor, where in the motor controller is configured to calculate the necessary sequence and duration of each powered off/powered on portion of each cycle.

FIG. 4E illustrates a conditioned voltage output 420 and a corresponding conditioned current output 421 sent to a motor, with 1.5 cycles passing through to the motor windings over a certain number of cycles, according to an aspect. As shown in FIG. 4E, those cycles passing through to the motor windings are powered on at a defined cycle angle. It is important to note that in the operation of an AC motor, the magnetic field is generated by the flow of current into the windings. Furthermore, the magnetic field strength generated in the motor windings is proportional to the amount of current flowing through the windings. This magnetic field creates the magnetic poles that causes the motor's rotor to spin as the foundation of a motor design. Therefore, by controlling the current waveform into the motor winding in a precise manner, the energy consumed by the motor can be optimized, while still achieving its required workload. FIG. 4E illustrates that even though the output voltage sent into the motor's winding is not a smooth sine wave, the current waveform is sinusoidal on the positive and negative halves of its cycle. This smooth sinusoidal current waveform 421 helps prevent the windings from overheating, in contrast with the rectangular digital waveform used in VFDs. As is illustrated in FIG. 4E, the average current is lower due to the turning off and on of the voltage output waveforms 420, and thus the energy consumption is reduced.

FIG. 4F illustrates a conditioned output voltage 422 sent into the motor winding, wherein the passed through waveforms reduce their average amplitude from cycle 1 to cycle 2 to cycle 3, until the cycle stops passing through or is skipped, according to an aspect. As shown in FIG. 4F the conditioned voltage waveform 422 can be made to be turned off and on at different times, as articulated by the power on points 422a-422f As is understood, the corresponding current waveform (not shown) for the output signal 422 of FIG. 4F would show a longer break between the positive and negative halves of a cycle. As the motor load increases, the amount of time the conditioned output voltage 422 is turned off (e.g., the duration of the powered off portions, such as powered off portions 430a-430c of FIG. 4C) can be shortened, to allow more power to be sent to the motor to drive the load. As the load reduces, the duration of time the conditioned voltage waveform 422 is turned off can be lengthened to save more energy. Note that this is applicable for each cycle of the 60 Hz or 50 Hz input signal. The other aspect of the control is skipping complete or partial cycles of the input signal, which will provide another aspect of controlling the motor speed, torque and loads.

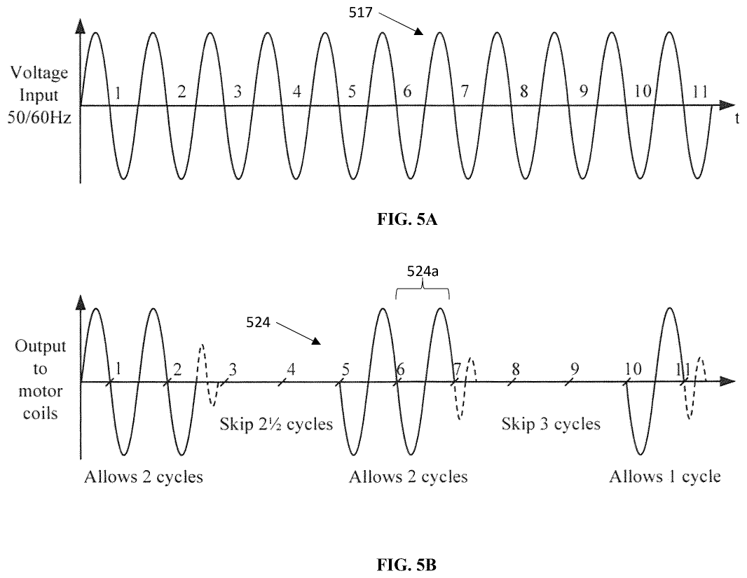

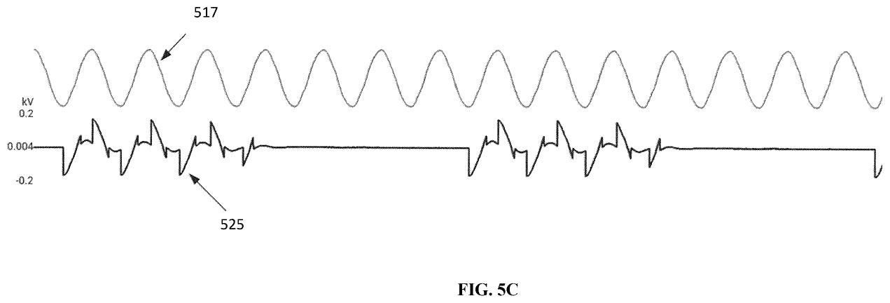

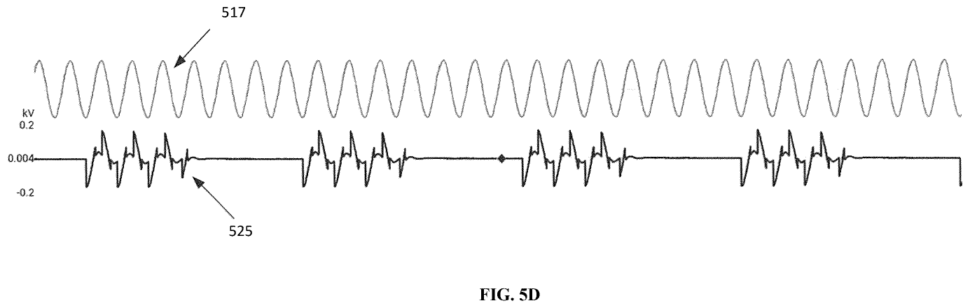

For clarity, a “skipped cycle” (“skipped signal cycle”) refers to a signal cycle present in the voltage or current input signal/waveform (such as that shown in input signal 417) that is omitted and not sent to the motor in the resultant voltage output signal, and thus replaced with a period of 0 voltage or 0 current being sent to motor, resulting in the motor not being actively powered for said duration. For example, the second cycle 417b from the voltage input signal 417 of FIG. 4A is skipped in the voltage output signal 423 sent to the motor coil, as shown in FIG. 4B. In an embodiment, multiple signal cycles/periods may be skipped at a time, thus sending multiple cycles having 0 volts/0 current to the motor, as will be described in FIG. 5B. While the input and output signals/waveforms of FIG. 4A-5B may be identified as displaying voltages (where applicable), it should be understood that the waveforms may be representative of a voltage or a current. For simplicity, the voltage or current waveforms of FIGS. 4A-5B and 7A-7C may be referred to simply as signals/waveforms. As such, the corresponding waveforms 417, 517 and 717 of FIGS. 4A, 5A and 7A may be representative of input signals/waveforms received by a corresponding controller unit from the power source, whereas the waveforms 423, 418, 419, 422, 524, 525, 726 and 727 of FIGS. 4B, 4C, 4D, 4F, 5B, 5C, 5D, 7B and 7C may be representative of output signals/waveforms sent to a corresponding motor from the motor controller module.

This method of skipping certain signal cycles instead of sending them to the motor may be configured to ensure that power is only delivered to the motor as needed to maintain suitable motor operation. This method of only providing the power that is required to sustain suitable motor operation may be used to save energy, thus reducing the operating costs associated with using a motor controlled by the disclosed motor controller drive. As described hereinabove, the power provided to the motor during the signal cycles that are not skipped (such as cycle 423a of FIG. 4B) is configured to provide the motor with sufficient inertia (and magnetic flux) to maintain suitable motor rotation/function during the cycles that are skipped (such as cycle (2) of FIG. 4B). As seen in FIG. 4B, voltage over-shoot, as articulated by the dotted lines of the waveform/signal in FIG. 4B, may be present in an voltage output signal sent to the motor. As is understood, this voltage over-shoot facilitates powering of the motor while power from the power source is not being actively supplied to the motor, as described hereinabove.

FIG. 5A illustrates a voltage input 517 to the motor controller drive, according to an aspect. FIG. 5B illustrates a conditioned voltage output 524 to a motor coil, wherein multiple cycles are skipped, according to an aspect. In an embodiment, the disclosed motor controller drive may be configured to skip multiple consecutive signal cycles of a voltage input signal 517 before sending it to a motor as a voltage output signal 524, rather than just skipping singular signal cycles at a time, as shown in FIG. 4B. As is understood in FIG. 5B, the controller unit of a motor controller drive may be configured to manipulate the corresponding switches of the motor controller drive, such that it allows two consecutive signal cycles of the input signal 517 into the motor windings (as part of the output signal 524), then skips two and a half consecutive signal cycles, then allows another two consecutive signal cycles of the input signal into the motor windings, then skips consecutive three signal cycles before allowing one signal cycle of the input signal into the motor windings. As shown in FIG. 5B, in an embodiment, the motor controller module may be configured to manipulate the input signal to generate the output signal by skipping whole cycles, half cycles, and other applicable portions of cycles, as described herein.

FIG. 5C illustrates a conditioned voltage output 525 to a motor coil, wherein approximately 3.5 cycles are passed through, and 4 cycles are skipped, according to an aspect. FIG. 5D illustrates an expanded timeline of FIG. 5C to show the number of cycles passing through to the motor winding are periodic and can be controlled or adjusted, according to an aspect. As is understood, FIG. 5C illustrates an embodiment wherein the speed of the motor can be controlled by controlling the number of cycles of the input signal that are skipped in the conditioned voltage output 525 sent to the motor. As can be seen in FIG. 5C, approximately 3.5 cycles are passed through (sent to the motor), and 4 cycles are skipped, such that over a total of 8 cycles, approximately 3.5 conditioned voltage output cycles are passed through to the motor winding. The approximate/effective frequency of the signal is changed from 50 Hz in the input signal 517 to 20 Hz in the conditioned output signal 525, for instance. This embodiment of FIG. 5C illustrates that the amplitude of the cycles passing through to the motor windings also starts to reduce (e.g., RMS voltage starts to reduce) by changing the power off and power on durations within each cycle itself. However, the amplitude of the output waveform could stay the same (as the input waveform) as needed, or increase or then decrease as needed, as the control of the power off and power on durations may be independently controlled by the controller unit.

In an embodiment, the motor controller drive can control three different “dimensions” of the voltage and current being sent into the motor winding. The first dimension is the control of each waveform cycle. As illustrated by FIG. 4C, each voltage waveform can be “turned off” just before the magnetic fields generated at the stator's change polarity as the voltage waveform swings from positive to negative in a 50 Hz or 60 Hz cycle, and “turned on” again after the overshoot/undershoot of the residual magnetic flux have died down (e.g., is about collapse), so that the rotor continues to rotate, thus saving energy. In some aspects, manipulating the input signal to skip at least a portion of at least one signal cycle may comprise varying the waveform of the output signal in each cycle of the at least one signal cycle. As illustrated in FIG. 4B-4F, varying the waveform of the output signal in each cycle of the at least one signal cycle may comprise any one of: powering off and subsequently powering back on a part/portion of the signal cycles (e.g., powering off for a power of duration within a signal cycle/partially skipping a cycle) as illustrated in FIG. 4C, varying the time duration for each powered off portion in a signal cycles (e.g., modifying the duration of each powered off portion) as illustrated in FIG. 4D, adjusting the break/delay between the positive and negative halves of the signal cycles as illustrated in FIG. 4F, or a combination thereof.

The second dimension is the control of when to start the skipping of cycles over a determined number of cycles. As is understood, the periodic start of skipped cycles can be controlled and varied to control the speed of the motor. As such, if the skipping occurs every X number of cycles, this X number can be varied to control the motor speed. In some aspects, manipulating the input signal to skip at least a portion of at least one signal cycle may comprise varying a periodicity of the at least one signal cycle that is skipped.

The third dimension is the control of the number of skipped cycles and number of pass-through cycles to the motor windings. For X total number of cycles from the input signal, Y number of cycles can be allowed to pass-through to the motor, and thus the number of cycles that are skipped is X minus Y Having a greater number of skipped cycles will result in lower energy consumption and lower motor speed and/or torque during non-heavy motor loading conditions, for instance. Also, for those cycles passing through to the motor windings, the amplitude can be changed to gradually reduce the power into the motor winding before the next set of cycles occurs. This is to ensure the motor rotor spins and will continue to spin smoothly. In some aspects, manipulating the input signal to skip at least a portion of at least one signal cycle may comprise varying a number of the at least one signal cycles that are skipped. As illustrated in FIG. 5B, the number of skipped cycles and the number of cycles that pass through could be varied dynamically.

It should be understood that the controller unit of the motor controller drive may control the pattern of allowed/skipped signal cycles present in the signal sent to the motor. Furthermore, as disclosed hereinabove, the controller unit may also be configured to receive feedback from the motor regarding motor operation, such that in the event that the motor is not being provided sufficient power to maintain suitable operation, that that skipped cycles may be replaced with allowed/passed through cycles, to increase power flow to the motor as needed. Again, by skipping certain cycles (not sending the signal cycles to the motor) that are not necessary for maintaining motor performance, power consumption may be reduced.

It should be understood that each mechanism of conditioning a voltage signal to save energy described herein may be utilized in conjunction with each other in the same conditioned output signal sent to a motor. For example, a conditioned voltage output sent to a motor may have a combination of skipped whole cycle (as seen in voltage output 423 of FIG. 4B), skipped partial cycles (as seen in voltage output 524 of FIG. 5B or voltage output 418 FIG. 4C). Furthermore, in an embodiment, the selective utilization of either of these three conditioning mechanisms may be determined based upon the requirements of the motor during operation. In an embodiment, the specific utilization of each conditioning method may be determined by the controller unit, such as controller unit 201 of FIG. 2, wherein the controller unit is configured to selectively utilize at least one conditioning method to generate a conditioned output signal to send to the motor, in order to save energy by only providing the motor with the power required to attain proper motor operation.

For clarity, it should be understood that skipped partial cycles may either have powered off portions that align with start/end of a signal cycle, as shown in FIG. 5B, wherein 2.5 cycles are skipped, or powered off portions that do not align with the start/end of a signal cycle, as shown in FIG. 4C, wherein portions of corresponding signal cycles are powered off that are not started/ended based upon the start/end of a signal cycle. As mentioned above, the duration of powered off portions that do not align with the start and end of a signal cycle may be dynamically determined by the controller unit in order to maximize energy savings while maintaining the required motor function.

In an embodiment, the conditioned output signal 524 of FIG. 5B may be modified in order to also utilize partially powered off cycles that do not start and stop based on the periodicity of the input cycle, such as the partially powered cycle 418d of FIG. 4C. For example, in an alternative embodiment, cycle 524a of conditioned output signal 524 of FIG. 5B may be replaced with cycle 418d of conditioned output signal 418 of FIG. 4C. In this way, the power sent to the motor during the corresponding replaced cycle of this embodiment of conditioned output signal 524 may be further reduced (when compared to that of cycle 524a. In the above alternative embodiment, the cycle used to replace cycle 524a may be adjusted to have the same period/frequency as cycle 524a, as to not modify the positioning and periodicity of adjacent cycles.

In an embodiment, repeated consecutive whole or partial signal cycles sent to the motor may lead to harmonic-based motor operational issues, such as increased motor vibrations, increased sound generation, etc. In said embodiment, the generated output signal may be modified to also include partially powered off cycles configured to avoid said issues by preventing consecutive identical waveforms patterns from being sent to the motor. In said embodiment, at least one partial signal cycle may be skipped after a set quantity of cycles that are passed through to the motor.

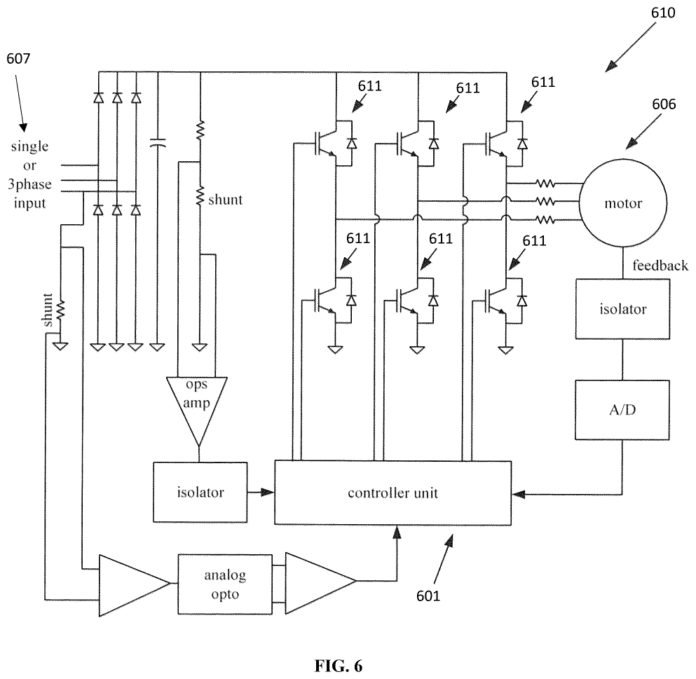

FIG. 6 illustrates a schematic diagram of a modified variable frequency drive 610 having a controller unit 601, according to an aspect. In an embodiment, the disclosed motor controller drive system may be configured to use all digital controls, similarly to existing VFD, but may only allow full 60 hz signals to turn on and off as it enters the motor windings, such as in the disclosed modified variable frequency drive 610. The disclosed modified VFD drive 610 of FIG. 6 may utilize the same practice of only powering the motor for one or more cycles before ceasing powering of the motor (e.g., skipping cycles) for a set amount of cycles, thus allowing the inertia and residual magnetic flux of the motor to facilitate continued operation of the motor while it is not being actively powered. As is understood, the controller unit 601 of this modified VFD 610 may be configured to facilitate selective powering of the motor 606 to save energy by receiving an input signal, and generating an output signal that skips certain signal cycles of the input signal, before outputting the resultant output signal to the motor 606. As is understood, by temporarily ceasing power output to the motor 606, energy consumption may be reduced, and the inertia/momentum and residual magnetic flux of the motor may be used to continue its rotation/operation while not being actively powered.

In an embodiment, the controller unit 601 may be configured to control six digital switches 611 to create pulse width modulations (PWMs) in order to facilitate the manipulation of the output signal sent to the motor, as seen in FIG. 6. In said embodiment, each digital switch 611 may be a transistor, MOSFET gate drive, or a similar switch configured to facilitate the corresponding functionality described herein. As such, in a manner similar to controller unit 201 of FIG. 2 being configured to actuate the corresponding first and second switches 202, 203, the controller unit 601 of FIG. 6 may be configured to actuate the six digital switches 611, in order to control which signal cycles of the input signal are skipped in the output signal sent to the motor 606. It should be understood that the disclosed modified VFD 610 of FIG. 6 may be classified as a type of motor controller drive, as much like the motor controller drives 200, 300 of FIG. 2-3, the modified VFD of FIG. 6 is also configured to control the operation of an associated motor 606.

In general, a similar method of operation may be employed in the operation of the corresponding motor in each motor controller drive, including the motor 606 of the modified VFD 610 of FIG. 6. In an embodiment, a method of operating a motor controller module is provided, the motor controller module comprising a controller unit 601 and a plurality of digital switches in electrical communication with the controller unit 601, wherein the motor controller module is in electrical communication with a power source 607 and a motor 606, the method comprising the steps of: obtaining an input signal from the power source 607, generating an output signal by manipulating the input signal using the digital switches 611 to skip at least a portion of at least one signal cycle, and outputting the output signal for transmission to the motor 606. The method may be performed by a controller unit, wherein said controller unit is a component of the motor controller module, such as the controller unit 101, 201, 301 and 601 as illustrated in FIGS. 1, 2, 3 and 6. The exact structures and mechanisms utilized to achieve the desired “cycle skipping” disclosed herein may vary between motor controller drive embodiments, but the resultant cycle skipping may be achieved in each embodiment through the utilization of appropriate firmware/software using feedback from the motor loading with the corresponding controller unit 601.

In an embodiment, the measured line current into the motor, the precise speed of the motor, sound of the motor, temperatures and loads of associated components (including but not limited to coils in the motor, motor bearings, rotor, shaft, etc.) in the overall motor system (e.g., the system comprising the motor controller module), rotational speed of the motor (RPM), tension and pressure on an associated conveyor belt using a transducer, torque of the shaft, etc., can be used to determine the approximate motor load. This can be achieved using a suitably configured artificial intelligence (AI) chip set to utilize these variables to determine the approximate motor loading. In an embodiment, the disclosed modified VFD 610 may utilize artificial intelligence (AI) as a means to determine the loading of a motor and, with feedback from the corresponding controller unit 601, determine when to skip signal cycles to maintain motor performance while saving energy. In an embodiment, autonomous decision making by the controller unit 601, including but not limited to determining whether the actuation of the one or more of the plurality of digital switches 611 is to be adjusted and how to adjust the actuation of the digital switches 611, may be implemented using artificial intelligence algorithms.

FIG. 7A illustrates a voltage output to a motor coil for a typical variable frequency drive, according to an aspect. FIG. 7B illustrates a voltage output to a motor coil for a modified variable frequency drive, wherein one cycle is skipped, according to an aspect. FIG. 7C illustrates a voltage output to a motor coil for a modified variable frequency drive, wherein partial cycles are skipped, according to an aspect. As seen in FIG. 7A-7C, the disclosed modified VFD 610 of FIG. 6 may be configured to utilize pulse width modulation (PWM).

For a modified variable frequency drive utilizing PWM, the controller unit may be configured to implement the cycle skipping practice described herein. As is shown in FIG. 7B-7C, the controller unit 601 of the modified variable frequency drive 610 of FIG. 6 may be configured to receive an input signal 717 having a first frequency and output an output signal having a second frequency to the motor, as well as skip whole signal cycles, as seen in FIG. 7B, or partial signal cycles, as seen in FIG. 7C. The skipping of partial or whole signal cycles may be done through utilization of appropriately timed PWM voltage pulses 728, as seen in FIG. 7B-7C, wherein the specific placement of the PWM voltage pulses may be configured to emulate an corresponding analog signal 726, 727 having skipped cycles/partial cycles. As is understood, the skipping of whole or partial signal cycles may allow the disclosed motor controller drive to use less energy to maintain motor operation, while still facilitating proper motor function.

Some aspects described herein relate to a non-transitory computer-readable medium that stores a set of instructions for operating a motor controller module by a controller unit. The set of instructions, when executed by one or more processors of the controller unit, may cause the controller unit to obtain an input signal from the power source. The set of instructions, when executed by one or more processors of the controller unit, may further cause the controller unit to generate an output signal by manipulating the input signal to skip at least a portion of at least one signal cycle. This manipulation of the input signal may be done through the controller unit actuating the switches of the corresponding motor controller module, as disclosed herein. The set of instructions, when executed by one or more processors of the controller unit, may further cause the controller unit to output the output signal for transmission to the motor.

The order in which the methods are described is not intended to be construed as limiting, and any number of the described acts can be combined in any order to implement the method, or an alternate method. Furthermore, the method can be implemented in any suitable hardware, software, firmware, or combination thereof, such that a corresponding device can implement the method. In an embodiment, the method is stored on one or more computer-readable storage medium/media as a set of instructions (e.g., computer-readable instructions or computer-executable instructions) such that execution by a processor of a computing device causes the computing device to perform the method. The term “unit” as used herein generally represents software, firmware, hardware, whole devices or networks, or a combination thereof. In the case of a software implementation, for instance, these may represent program code that performs specified tasks when executed on a processor (e.g., CPU or CPUs). The program code can be stored in one or more computer-readable memory devices, such as computer-readable storage media. The features and techniques of the unit are platform-independent, meaning that they may be implemented on a variety of commercial computing platforms having a variety of processing configurations.

It may be advantageous to set forth definitions of certain words and phrases used in this patent document. The term “couple” and its derivatives refer to any direct or indirect communication between two or more elements, whether or not those elements are in physical contact with one another. The term “or” is inclusive, meaning and/or. As used in this application, “and/or” means that the listed items are alternatives, but the alternatives also include any combination of the listed items.

The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like.

Further, as used in this application, “plurality” means two or more. A “set” of items may include one or more of such items. The terms “comprising,” “including,” “carrying,” “having,” “containing,” “involving,” and the like are to be understood to be open-ended, i.e., to mean including but not limited to. Only the transitional phrases “consisting of” and “consisting essentially of,” respectively, are closed or semi-closed transitional phrases.

Throughout this description, the aspects, embodiments or examples shown should be considered as exemplars, rather than limitations on the apparatus or procedures disclosed or claimed. Although some of the examples may involve specific combinations of method acts or system elements, it should be understood that those acts and those elements may be combined in other ways to accomplish the same objectives.

Acts, elements and features discussed only in connection with one aspect, embodiment or example are not intended to be excluded from a similar role(s) in other aspects, embodiments or examples.

Aspects, embodiments or examples of the invention may be described as processes, which are usually depicted using a flowchart, a flow diagram, a structure diagram, or a block diagram. Although a flowchart may depict the operations as a sequential process, many of the operations can be performed in parallel or concurrently. In addition, the order of the operations may be re-arranged. With regard to flowcharts, it should be understood that additional and fewer steps may be taken, and the steps as shown may be combined or further refined to achieve the described methods.

Although aspects, embodiments and/or examples have been illustrated and described herein, someone of ordinary skills in the art will easily detect alternate of the same and/or equivalent variations, which may be capable of achieving the same results, and which may be substituted for the aspects, embodiments and/or examples illustrated and described herein, without departing from the scope of the invention. Therefore, the scope of this application is intended to cover such alternate aspects, embodiments and/or examples. Hence, the scope of the invention is defined by the accompanying claims and their equivalents. Further, each and every claim is incorporated as further disclosure into the specification.

What is claimed is:

1. A motor controller module configured for electrical communication with a motor and a power source, the motor controller module comprising:
a controller unit;
an optocoupler configured for electrical communication with the controller unit and the power source;
an optotriac configured for electrical communication with the controller unit; and
a plurality of switches, wherein each switch of the plurality of switches is configured for electrical communication with the optotriac and the motor;
wherein the motor controller module is configured to receive an input signal from the power source, wherein the controller unit is configured to manipulate the received input signal by actuating at least one switch of the plurality of switches to generate an output signal, wherein the output signal skips at least one portion of a signal cycle of the input signal, and transmit the output signal to the motor.

2. The motor controller module of claim 1, wherein the motor controller module is in electrical communication with the motor over a feedback path, wherein the feedback path is configured to carry motor operation feedback information from the motor to the controller unit, and the controller unit is configured to selectively modify the output signal sent to the motor based upon the motor operation feedback information.

3. The motor controller module of claim 1, wherein each switch of the plurality of switches is a digital switch.

4. The motor controller module of claim 1, wherein the controller unit is selected from a group of controlling units, the group of controlling units consisting of: an analog processing unit, an optical processing unit, a graphics processing unit, and a microcontroller unit.

5. A motor controller module comprising:
a controller unit configured for electrical communication with a motor and a power source;
a plurality of switches, wherein each switch of the plurality of switches is configured for electrical communication with the controller unit and the motor;
wherein the motor controller module is configured to receive an input signal from the power source, generate an output signal by manipulating the input signal to skip at least a portion of at least one signal cycle and transmit the output signal to the motor, wherein the controller unit is configured to receive the input signal and manipulate the input signal by selectively actuating at least one switch of the plurality of switches.

6. The motor controller module of claim 5, wherein each switch of the plurality of switches is a digital switch.

7. The motor controller module of claim 6, wherein each digital switch of the plurality switches is a transistor.

8. The motor controller module of claim 5, further comprising an optocoupler in electrical communication with the power source and the controller unit and an optotriac in electrical communication with the controller unit and the plurality of switches.

9. The motor controller module of claim 5, wherein the motor controller module is in electrical communication with the motor over a feedback path, wherein the feedback path is configured to carry motor operation feedback information from the motor to the controller unit.

10. The motor controller module of claim 9, wherein the controller unit is configured to selectively manipulate the output signal based upon the motor operation feedback information received from the motor.

11. The motor controller module of claim 5, wherein the controller unit is selected from a group of controlling units, the group of controlling units consisting of: an analog processing unit, an optical processing unit, a graphics processing unit, and a microcontroller unit.

12. A method of operating a motor using a motor controller module, wherein the motor controller module is configured for electrical communication with the motor and a power source, the motor controller module having: a controller unit configured for electrical communication with the power source and a plurality of switches, wherein each switch of the plurality of switches is configured for electrical communication with the controller unit, the method comprising the steps of:
obtaining an input signal from the power source;
generating an output signal by manipulating the input signal to skip at least a portion of the input signal through selective actuation of at least one switch of the plurality of switches; and
transmitting the output signal to the motor.

13. The method of claim 12, wherein manipulating the input signal to skip at least a portion of the input signal comprises skipping at least one whole signal cycle of the input signal.

14. The method of claim 12, wherein manipulating the input signal to skip at least a portion of the input signal comprises skipping at least one half cycle of the input signal.

15. The method of claim 12, wherein manipulating the input signal to skip at least a portion of the input signal comprises skipping at least one partial cycle of the input signal, wherein the generated output signal comprises at least one powered on portion, at least one power off point, at least one powered off portion and at least one power on point, wherein the at least one power off point is positioned at a non-zero voltage of the output signal.

16. The method of claim 12, further comprising receiving motor operation feedback information from the motor and modifying the output signal based upon the motor operation feedback information.

17. The method of claim 16, wherein modifying the output signal based on the motor operation feedback information comprises decreasing a quantity of skipped portions of the at least a portion of the input signal skipped.

18. The method of claim 12, wherein each switch of the plurality of switches is a digital switch, such that the controller unit is configured to actuate the plurality of digital switches to create pulse width modulations to generate the output signal.

19. The method of claim 12, further comprising the steps of:
performing an analog to digital conversion of the input signal;
performing digital signal processing on the input signal;
performing a digital to analog conversion on the input signal to generate an analog signal; and
sending the generated analog signal to the plurality of switches to selectively actuate the plurality of switches.

20. The method of claim 12, further comprising autonomously actuating at least one switch of the plurality of switches based upon an artificial intelligence algorithm.
